(19) United States
(12) Patent Application Publication
(10) Pub. No.: US 2025/0007241 A1
(43) Pub. Date: Jan. 2, 2025

(54) LASER DIODE BASED SYSTEMS, SUBSYSTEMS AND METHODS WITH TEMPERATURE CONTROL

(71) Applicant: ELBIT SYSTEMS ELECTRO-OPTICS - ELOP LTD., Rehovot (IL)

(72) Inventors: Yoav LAVON, Rehovot (IL); Matan Ori BASSAN, Rehovot (IL); Naftali SHCHERANSKI, Rehovot (IL); Ohad BAUM, Rehovot (IL); Moshe MOSCOWITZ, Rehovot (IL)

(21) Appl. No.: 18/885,771

(22) Filed: Sep. 16, 2024

Related U.S. Application Data
(63) Continuation of application No. PCT/IL2023/050314, filed on Mar. 27, 2023.

(30) Foreign Application Priority Data
Mar. 27, 2022 (IL) 291729

(51) Int. Cl. H01S 3/102; H01S 3/0941; H01S 5/0237; H01S 5/024; H01S 5/40

(52) U.S. Cl. CPC H01S 5/02415; H01S 3/0941; H01S 3/1022; H01S 5/0237; H01S 5/02476; H01S 5/4025

(57) ABSTRACT

Systems subsystems and methods for controlling temperature of a laser diode (LD) stack including at least one LD bar of at least one LD emitter, for achieving a desired temperature of the LD stack and corresponding emission wavelength of the LD emitter(s) of the stack, using: a thermal unit (TU) for controlling temperature of the LD bar/stack; a measuring device for detecting updated ambient temperature in an area of the LD bar; and a main controller controlling operation of the TU, for achieving the desired temperature and its corresponding emission WL. At least one side of the TU is in direct thermal contact with a corresponding side of each LD stack, forming a contact surface area S1 between the TU and the LD stack, where the size of S1 corresponds to a size of an overall TU contact surface area S2 facing the LD stack to reduce temperature control speed.

### FIELD OF THE INVENTION

The present disclosure relates in general to systems, methods, units and/or devices that are based on laser diode light emitters with thermal control, and more particularly to systems, methods, units and/or devices that enable temperature of stack(s) or bar(s) of laser diode emitters' stabilization and controlling.

### BACKGROUND

Many systems that use one or more laser diodes, often require achieving and/or stabilization of temperature in an area of the laser diode(s) for achieving an optimal or desired optical performances of the diode(s) such as a desired output wavelength.

Many laser diodes output light of different wavelengths or different wavelengths bands under different temperatures and may have a typical sensitivity of 0.27 nm (nano-meters) in wavelength, per change of each single degree Celsius.

Diode pumped solid state laser (DPSSL) systems typically use a solid-state gain medium having specific spectral absorption characteristics for producing optimal pump gain (herein “optimal lasing”). To enable optimal lasing, a light source is used, typically including a diode stack including one or more laser diode emitters such as one or more light emitting diodes (LEDs) enabling outputting light in one or more wavelengths that correspond to the one or more absorption lines/wavelengths of the gain medium.

However, the wavelength(s) or wavelength band(s) outputted by the laser diode emitters can be extremely sensitive to temperature and temperature changes (temperature change gradients) and can dramatically deviate from the desired output optical property(ies) such as desired output wavelength. When the temperature in an area of the laser diode stack deviates from a desired temperature or from a desired temperature range, causing a dramatic reduction in DPSSL system performances such as reductions in gain, power/energy output, deteriorated throughput beam quality, etc. It is therefore crucial to maintain or achieve temperature stability of the laser diode(s) throughout the operating temperatures range of the DPSSL system.

Many DPSSL systems often require activation a while before they are required to be actually operated. Reaching the desired temperature for their optimal gain from an ambient temperature of the specific DPSSL system's environment (e.g., by heating/cooling of the laser diode(s)), takes time. Often several dozens of seconds or even minutes, depending on the difference between the desired temperature for optimal gain, and the actual ambient temperature surrounding the diodes, and/or the total mass of the diodes and their mounts that require heating/cooling. This requires planning ahead the activation time of the diodes, in respect to the DPSSL system's actual required operation time, based on the required time to bring the laser diodes to the desired operating temperature. In many cases the DPSSL system is required to be maintained in a standby mode, so it is required to keep its desired temperature (optimal mode), in order to enable DPSSL system operation in any given moment as well as unknown/unexpected required operation timings, which leads to system unavoidable power consumption hence inefficiency due to considerable large mass of material that needs to be kept at a specific desired temperature that can differ by tens of degrees from the environmental (ambient) temperature.

### SUMMARY

Aspects of disclosed embodiments pertain to a laser diode subsystem comprising at least:
(i) a laser diode (LD) assembly comprising at least one LD stack that comprises at least one LD bar each LD bar comprising at least one LD emitter, wherein the at least one LD emitter of each LD bar has at least one emission wavelength (WL) when operated at a corresponding desired operation temperature Td; and
(ii) a temperature control subsystem comprising at least:
a thermal unit (TU) configured to control temperature of the at least one LD emitter of a corresponding LD stack;
at least one measuring device configured to detect at least one updated temperature-related parameter value of the at least one LD emitter of the LD stack, the at least one updated temperature-related parameter value being associated with an updated ambient temperature Ta in an area of the at least one LD emitter; and
a main controller operatively associated with the TU and with the at least one measuring device, for controlling operation of the TU, based on the detected updated temperature related parameter value and the at least one desired operation temperature Td of the at least one LD emitter, where at least one side of the TU is in direct contact with a corresponding side of each LD stack of the laser diode assembly for direct thermal contact between the TU and each LD stack, forming a contact surface area S1 between the TU and the corresponding LD stack.

According to some embodiments, a size of the contact surface area S1 may be smaller than or equal to a size of an overall TU contact surface area S2 facing the LD stack such that S1≤S2, and a ratio “R” between S1:S2 is such as to reduce a mass to be heated or cooled by the TU, for increasing temperature-control speed, by reducing time of adjusting of the temperature of the at least one LD emitter from an updated ambient temperature Ta to a desired operation temperature Td, wherein the desired operation temperature Td corresponds to a desired emission wavelength (WL) of the at least one emitter.

Aspects of disclosed embodiments further pertain to a diode-pumped solid-state laser (DPSSL) system comprising at least:
(i) a laser diode (LD) assembly comprising at least one LD stack that comprises at least one LD bar, each LD bar comprising at least one LD emitter, each LD emitter being configured to emit light of at least one emission wavelength (WL) when under a corresponding at least one emission desired operation temperature Td;
(ii) a solid-state (SS) gain medium; and
(iii) a thermal unit (TU) configured to control temperature of the LD stack;
(iv) at least one measuring device configured to detect at least one updated temperature-related parameter value of the at least one LD emitter, the updated temperature-related parameter value being associated with an updated ambient temperature Ta in an area of the at least one LD bar, where the at least one desired operation temperature Td of the at least one LD emitter of each LD bar, corresponds to absorption properties of the gain medium, and
(iv) a main controller operatively associated with the TU and with the at least one measuring device, for controlling operation of the TU, based on the detected updated temperature related parameter value and the at least one desired operation temperature Td of the at least one LD emitter, where at least one side of the TU is in direct contact with a corresponding side of each LD stack of the laser diode assembly for direct thermal contact between the TU and each laser diode stack, forming a contact surface area S1 between the TU and the corresponding LD stack.

According to some embodiments at least one side of the TU may be in direct contact with a corresponding side of each LD stack of the laser diode assembly for direct thermal contact between the TU and each LD stack, forming a contact surface area S1 between the TU and the corresponding LD stack.

Additionally or alternatively, the system may be designed such that a size of the contact surface area S1 is smaller than or equal to a size of an overall TU contact surface area S2 facing the LD stack such that S1≤S2, (a ratio “R” between S1:S2 is equal to or smaller than 1:R≤1) such as to reduce a mass to be heated or cooled by the TU, for increasing temperature-control speed, by reducing time of adjusting of the temperature of the at least one LD emitter from an updated ambient temperature Ta to a desired operation temperature Td, wherein the desired operation temperature Td corresponds to a desired emission wavelength (WL) of the at least one emitter.

Other aspects of disclose embodiments pertain to a method for temperature control, the method comprising at least:
providing a laser diode assembly comprising at least one laser diode (LD) stack that comprises at least one LD bar, each LD bar comprising at least one LD emitter, each LD emitter being configured to emit light of at least one emission wavelength (WL) when under a corresponding at least one emission desired operation temperature Td;
providing a thermal unit (TU) configured to control temperature of the at least one LD emitter;
providing at least one measuring device;
detecting at least one updated temperature-related parameter value of the at least one LD emitter, the updated temperature-related parameter value being associated with an updated ambient temperature Ta in an area of the at least one LD emitter, using the at least one measuring device;
controlling operation of the TU, based on the detected updated temperature related parameter value and the at least one desired operation temperature Td of the at least one LD emitter, where at least one side of the TU is in direct contact with a corresponding side of each laser diode stack of the laser diode assembly for direct thermal contact between the TU and each laser diode stack, forming a contact surface area S1 between the TU and the corresponding LD stack.

### BRIEF DESCRIPTION OF THE FIGURES

The figures illustrate generally, by way of example, but not by way of limitation, various embodiments discussed in the present document.

For simplicity and clarity of illustration, elements shown in the figures have not necessarily been drawn to scale. For example, the dimensions of some of the elements may be exaggerated relative to other elements for clarity of presentation. Furthermore, reference numerals may be repeated among the figures to indicate corresponding or analogous elements. References to previously presented elements are implied without necessarily further citing the drawing or description in which they appear. The figures are listed below.

FIGS. 1A and 1B show a schematic illustration of a laser diode subsystem having a fast temperature-control of temperatures of a laser diode assembly, according to some embodiments: FIG. 1A shows a schematic illustration of the laser diode subsystem having a controllable thermal unit (TU) that is put in direct contact with a laser diode stack or laser diode bar or bars; and FIG. 1B shows an exemplary ratio between a surface area S2 of a contacting TU side that is coupled to a counter-facing side of the laser diode stack and a contacting surface area S1 representing the overall area of contact between the TU and the laser diode stack;

FIG. 2 shows a schematic illustration of a diode pumped solid state laser system that uses a laser diode subsystem as part thereof, for temperature control of laser diode stack(s) of a laser diode assembly, according to some embodiments;

FIG. 3 is a block diagram, schematically illustrating optional modules operable by a main controller of a laser diode subsystem, according to some embodiment;

FIG. 4 shows a schematic illustration of a laser diode subsystem, according to other embodiments;

FIGS. 5A and 5B show a laser diode subsystem having two thermistors for measuring laser diode emitters stack temperature, according to other embodiments: FIG. 5A shows an isometric view of the laser diode subsystem; and FIG. 5A shows a frontal view of the laser diode subsystem;

FIG. 6 is a flowchart, schematically illustrating a method for controlling temperature of a laser diode assembly, based on real time fast measuring of one or more parameter values associated with an updated temperature of a laser diode bar(s)/stack(s) of the laser diode subsystem, according to some embodiments;

FIGS. 7A and 7B show absorption characteristics of Nd:YAG gain medium (FIG. 7A), and emission spectrum of a laser diode emitter when in 70 degrees Celsius temperature of the emitter (for example) (FIG. 7B);

FIGS. 8A and 8B show time-dependent laser diode bar(s) simulated/calculated performances, indicative of subsystem's time-related responsivity rate, using a laser diode subsystem of some embodiments: FIG. 8A shows a TEC's calculated time-dependent power consumption behaviour; and FIG. 8B shows calculated time-dependent bar's temperature behaviour; and

FIGS. 9A-9C show calculated correlations in gain medium absorption based on bar's/emitter's temperature and emitter's wavelength. According to some embodiments: FIG. 9A shows gain medium absorption performances in relation to bar's/emitter's temperature; FIG. 9B shows gain medium absorption performances in relation to bar's/emitter's emission wavelength; and FIG. 9C shows a simulation correlated to the expected output energy and measured output energy from a solid state (Nd:YAG in this case) laser resonator versus temperature of the pumping laser diode emitter(s).

### DETAILED DESCRIPTION

Temperature controllers such as a thermoelectric cooler (TEC) can be used for heating, heat removal and/or cooling of a laser diode assembly including one or more laser diode stacks.

A TEC is a semiconductor device that includes two thermally conductive plates: a hot plate and a cold plate having a gap/distance therebetween in which alternating N-type and P-type semiconductor elements (e.g., alternating/N/P pillars) are placed.

According to some aspects of this disclosure, the purpose of one or more embodiments of the disclosed invention is to improve laser diode assemblies' temperature control speed, for reaching a desired operation temperature Td from an ambient temperature Ta of the laser diode emitter(s) of the laser diode assembly, in minimum time (at highest heating/cooling speed), in order to achieve a desired emission wavelength (WL) of the emitter(s) that corresponds to the desired operation temperature Td, in minimum time.

The term “emission wavelength” used herein may refer to a wavelength intensity peak of light emitted from the laser diode emitter(s).

Embodiments of laser diode subsystems disclosed, may be configured to enable faster heating and/or cooling of the laser diode emitter(s), especially yet not necessarily when the absolute value of a temperature gap between a desired operation temperature of the laser diode assembly Td, required for achieving a corresponding desired emitters' emission wavelength, and a (deduced/measured) ambient temperature of the laser diode emitter(s) Ta is high (e.g., over 50 or 60 degrees Celsius). This may allow, inter alia, complete deactivation of the laser diode assembly (and optionally other parts of a system it is embedded in) when the laser diode assembly is not required for operation. This improves energy consumption efficiency, while still enabling fast enough achievement of the desired operation temperature Td (for achievement of a desired emission wavelength) by heating/heat removal/cooling of the laser diode emitter(s) from ambient temperature Ta thereof that can be much higher or much lower than the desired operation temperature Td. E.g., enabling heating of the laser diode emitter(s) under an ambient temperature Ta, up to 50 degrees Celsius lower than the desired operation temperature Td in less than one or two seconds. Therefore, the laser diode assembly/emitter(s) can be quickly made ready to work in its optimal/desired operation temperature Td only when actually required for work/lazing and be kept deactivated (turned off) when not required.

The term “ambient temperature” or “updated ambient temperature” can be used interchangeably herein. These terms may refer to a temperature in a vicinity of the laser diode assembly or one or more of its laser diode emitters' bars or stacks and can be a temperature of a surrounding environment of the laser diode assembly/stack(s)/bar(s)/emitter(s) also when the laser diode emitter(s) is(are) not in operation (deactivated/disabled/turned off).

The term “desired operation temperature” used herein, may refer to a temperature value Td that corresponds to a desired emission wavelength WL of the laser diode emitter(s), due to known/measured correlation between emitter(s)'s temperature and outputted emission wavelength intensity peak. This means that the desired operation temperature Td is estimated to have the emitter(s) output light at an emission wavelength intensity peak that is desired for any desired requirements (depending of course on emission wavelength vs. temperature value behaviour, of the specific emitter(s) being used).

In order to achieve optimal (e.g., maximal) temperature-control speed: (i) the laser diode assembly may be put in direct contact with at least one side or surface of a thermal unit such as a TEC's hot plate. For example, by attaching/coupling/soldering the external surface of the hot plate of the TEC to a side of the laser diode stack(s)/bar(s) of the laser assembly; and (ii) the size (e.g., surface area) of the hot plate surface and/or of the entire TEC may be reduced to match a counter-facing surface area or a footprint area/volume of the laser diode stack(s). Such that the ratio R between the contact area S1 of the laser diode(s) touching the TEC and the overall surface area S2 of the TEC plate side that faces/is coupled to the laser diode stack(s)/bar(s) is as close to 1:1 as possible. For example, having a minimum ratio of 1:2 or 1:4:R≥0.5 or R≥0.25 (i.e., the contact surface area S1 occupies more than 50% or more than 25% of the surface area of the TU side that is coupled to the laser diode stack(s)/bar(s) such that they are as close to a 100% surface areas match (R=1) as possible).

In order to achieve high speed temperature-control, the updated ambient temperature Ta should be also measured by a measuring device such as a thermistor that has high sensing speed and/or output signal/data transmission speed to allow fast heating/cooling of the laser diode assembly based on most recent and real time updated ambient temperature related measurement and to avoid overheating/overcooling caused due to misread or delayed correct updated ambient temperature Ta. Fast determination (e.g., calculation) of a temperature difference DT between the updated ambient temperature Ta and (known) desired operation temperature Td: DT=Td−Ta; or DT=Ta−Td, may also be required, e.g., requiring hardware and/or software means capable of fast processing/analysis of received measuring device(s)' data/signals.

Aspects of disclosed embodiments pertain to a laser diode subsystem that includes at least: (i) a laser diode assembly having at least one laser diode stack that comprises at least one laser diode bar (LDB), each LDB comprising at least one laser diode emitter, each laser diode emitter of each LDB may have at least one desired operation temperature Td; and (ii) a temperature control subsystem configured for fast temperature measuring and fast control of the laser diode assembly's temperature by using a thermal unit (TU) such as a TEC, a heater, a heat sink etc.; and (iii) one or more measuring devices configured for direct or indirect measuring ambient temperature Ta in an area of the laser assembly.

According to some embodiments, at least one side of the TU is put in direct contact with a corresponding side of each laser diode stack/bar of the laser diode assembly, for direct thermal contact between the TU and each laser diode stack/bar, where the size of the TU corresponds to the size of the laser diode assembly, for reducing mass to be heated and/or cooled by the TU, in order to increase temperature-control speed for changing the temperature from measured/determined updated ambient temperature Ta to a desired operation temperature Td, in the most efficient manner (e.g., in a reduced/minimum temperature-control time and reduced/minimum emitters' and/or TU's overall power consumption operation time and/or energy consumption).

According to some embodiments, the temperature control subsystem may also include or be associated with a main controller operatively associated with the TU and with the measuring device(s), for controlling operation of the TU, based on updated temperature related parameter value, detected by the measuring device(s), to reach the at least one desired operation temperature Td of the at least one laser diode emitter.

According to some embodiments, wherein the direct contact between the side of the TU that is coupled to the laser diode stack(s)/bar(s) may be done by soldering of one side of each laser diode stack to the coupling side of the TU, by using a soldering material. The soldering material may have similar or same coefficient of thermal expansion (CTE) as that of the at least one side of the TU connecting to the at least one diode stack of the diode assembly and/or as that of the at least one side of each laser diode stack connecting to the TU.

According to some embodiments, each laser diode stack may further comprise spacers, separating the diode bars in each laser diode stack from one another. The spacers may be arranged such that the coupling (contacting) side of the TU is also in direct contact with the spacers of the respective laser diode stack.

According to some embodiments, the TU directly connects each laser diode stack such that light emitted from each of the laser diode emitters of each LDB of the diode stack is directed to a direction that is angular to the at least one TU connecting surface plane, forming a non-zero angle (e.g., between 30-150 degrees) between a surface or a plane of each TU connecting side and the direction of emitted light from each laser diode.

According to some embodiments, the entire operation of the laser diode subsystem may be automated.

According to some aspects of embodiments disclosed, the laser diode subsystem may be implementable as part of a DPSSL system that uses the laser diode assembly (placed in its gain/lasing cavity) for illuminating a solid-state gain medium made, for example, of a yttrium aluminum garnet (YAG) based material such as a doped YAG material, doped, for example, with one of: neodymium (Nd): Nd:YAG; ytterbium (Yb): Yb:YAG, thulium (Tm): Tm:YAG, holmium (Ho): Ho:YAG, erbium (Er):Er:YAG.

Nd:YAG gain medium has at least two optimal absorption wavelengths WL1/WL2 in the infrared (IR) range (WL1=795 nm and WL2=808 nm). Correspondingly, the laser diode emitters (herein also shortly referred to as “emitters”) of the laser diode assembly, may be configured to emit light in corresponding wavelengths WL1 and WL2, each achieved under a different temperature: Td1 or Td2. This may enable a more efficient operation such as faster obtainment of the desired temperature Td1/Td2 (for example, Td1=20 degrees Celsius and Td2=68 degrees Celsius for achieving Nd:YAG related emitters' corresponding wavelengths WL1 and WL2). Also a more economic power consumption of the thermal unit both timewise and energy-wise, by controlling the temperature for reaching one of the desired operational temperatures Td1 or Td2 that is either closer to the ambient temperature Ta corresponding to one of the gain medium's absorptions wavelengths: WL1 or WL2, respectively, or faster to reach. This allows efficient operation of the DPSSL in very large environment temperature range (e.g., larger than 100 degrees Celsius).

According to some embodiments, the laser diode subsystem may be configured to enable fast temperature measuring, fast temperature difference determination and fast temperature-control of a few seconds (e.g. up to 2 seconds), for a DPSSL systems that use Nd:YAG based gain medium having optimal absorptions corresponding to laser diode emitter(s) output wavelengths WL1 (795 nm) and WL2 (808 nm) and corresponding desired operation temperatures Td1 (20oC) and Td2 (68oC) for ambient temperatures Ta ranging that deviate from any of the desired operation temperatures Td1/Td2 up to 50 degrees Celsius.

For example, in cases in which the DPSSL system is located in environment(s) in which an ambient external temperature can range between (−30) to (+70) degrees Celsius: the main controller may determine (based on measured/determined exact updated ambient temperature Ta) which of the desired operation temperatures Td1 or Td2 is closer to the updated ambient temperature, and heat/cool the laser diode stack(s)/bar(s) to the determined closest desired operation temperature.

According to some embodiments, the TU may only be configured for active heating and for passive cooling e.g., by passive heat removal (optionally by enabling natural removal of heat through the TEC plates and/or through a heat sink/heat spreader or by applying a minimal current to it). In this case a DPSSL system based on Nd:YAG gain medium and embodiments of the laser diode assembly, may only require heating of the laser diode stack(s)/bar(s), in ambient temperatures ranging between (−30)-(+70) degrees Celsius to reach the closest desired operation temperature of 20/68 degrees Celsius, or the desired operation temperature Td1/Td2 that will be reached in minimum time. For example, in a case in which the ambient temperature Ta is 70oC, reaching the desired operation temperature Td2=68oC will only require heat removal or cooling of merely 2oC degree Celsius, which can be quickly achieved. In this particular example in which the ambient temperature is within a range of 100 degree Celsius: (−30)° C.-(+70)° C., the maximum temperature difference DTmax, required for heating/cooling to reach the closest/fastest desired operation temperature of 20° C. or 68° C., will be about ±50 degree Celsius.

According to some embodiments, since the heat removal or cooling speed Vc may be much slower than heating speed Vh: Vc<<Vh, a default decision making process may include determining which desired operation temperature Td1/Td2 is achieved faster, taking into consideration the differences between the cooling/heat removal and heating speeds and the temperature difference DT. In some cases, cooling/heat removal may only be carried out when the ambient temperature Ta exceeds the higher desired operation temperature Td2, where any other temperature below the highest desired operation temperature Td2 will result in a decision to heat the laser diode stack(s)/bar(s) to the closest desired operation temperature Td1/Td2. For example, an ambient temperature Ta of between (−30° C.) to (+67° C.) (including temperatures close to the lowest desired operation temperature Td1) may all require heating, where an ambient temperature Ta that is above the lower desired operation temperature Td1=20oC may require heating to reach the higher desired operation temperature Ta<Td2=68oC and an ambient temperature Ta that is below the lower desired operation temperature Ta<Td1=20oC may require heating to reach the lower desired operation temperature Td1=20oC. If the ambient temperature Ta is equal to one of the desired operation temperatures td1/Td2, TU may not be required for operation unless the temperature is further detected to deviate from the desired operation temperature, in order to stabilize it.

According to some embodiments, the laser diode assembly may include one or more power sources for powering the laser diode emitter(s), the TU, the main controller and the one or more measuring devices.

According to some embodiments, some or each of: the laser diode emitter(s), the TU, the main controller and the one or more measuring devices may be separately powered to enable operating (supplying power) the laser diode emitters and/or the TU only when required while still enabling continuous/periodic operation of the measuring device(s) and the main controller.

According to some embodiments, the main controller may be configured to separately control operation of the TU and the diode emitters and optionally also the one or more measuring devices.

According to some embodiments, one or more parameters may influence and therefore be designed to optimize temperature-control speed such as the ratio R between the overall or partial size, the overall or partial mass and/or dimensions of the TU in relation to an overall or partial size, mass and/or dimensions of the laser diode assembly/stack(s)/bar(s) or of a footprint of the diode assembly. Accordingly, the design of the laser diode subsystem may be such that any one or more of these ratios may be minimized or reduced. Materials from which at least contacting parts of the TU and laser diode assembly may also influence thermal heating/removal speeds and therefore temperature-control speed and can also be taken into consideration for the laser diode subsystem design to optimize (reduce/minimize) temperature-control speed.

The main controller may be implemented as or include a printed circuit board (PCB) and may be located in a vicinity of, externally to or remotely from the laser diode assembly. The PCB may be connected to and/or in communication with the TU and the at least one measuring device.

According to some embodiments, the TU side may be coupled to the laser diode stack(s)/bar(s) by way of soldering. The soldering materials may be of high thermal conductivity. Additionally, the soldering material(s) used for connecting the TU to the laser diode stack(s)/bar(s) may have a melting temperature that allows sequential (gradual) soldering of the TU and the stack(s)/bar(s).

According to some embodiments, the mass of the stack(s)/bar(s) or of the entire laser diode assembly may be reduced to less than 1 gram.

According to some embodiments, using a TEC at least as part of the TU that is put in contact with the laser diode stack(s)/bar(s), the TEC power densities may be typically 15 W/cm2 at least for heating.

According to some embodiments the TEC (hot and cold) plates may be made of a material such as Aluminium Nitride, AIN etc. that has a coefficient of thermal expansion (CTE) that corresponds (matches) to CTE of laser diode stack(s)/bar(s) or spacers placed between the laser diode emitters, to eliminate or reduce physical damages such as disconnection of the TU from the laser diode assembly when the laser diode subsystem is put under extreme ambient temperatures or experiences high temperature changes (high temperature gradients).

According to some embodiments, the one or more measuring devices may have a fast measuring properties, capable for example, of measuring temperature-related parameter value at speeds of several tenths of a second.

According to some embodiments, the ambient temperature of a parameter value associated therewith may be measured by using a device or an electrical circuitry that manipulates (e.g., biases) the input electrical current delivered to the laser diode emitter(s).

According to some embodiments, the DPSSL system may be carried as a payload of a manned or unmanned vehicle that is manually, automatically/autonomously and/or remotely controlled.

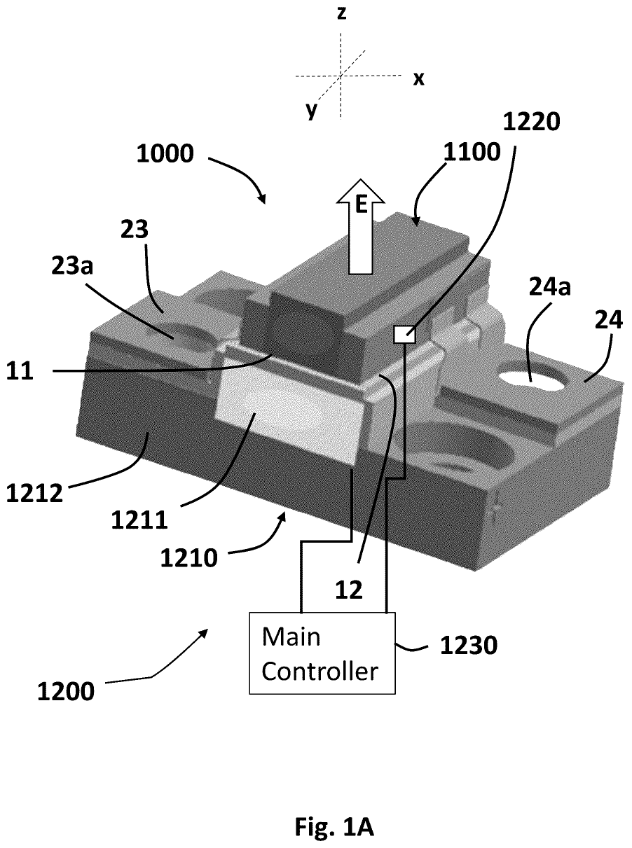

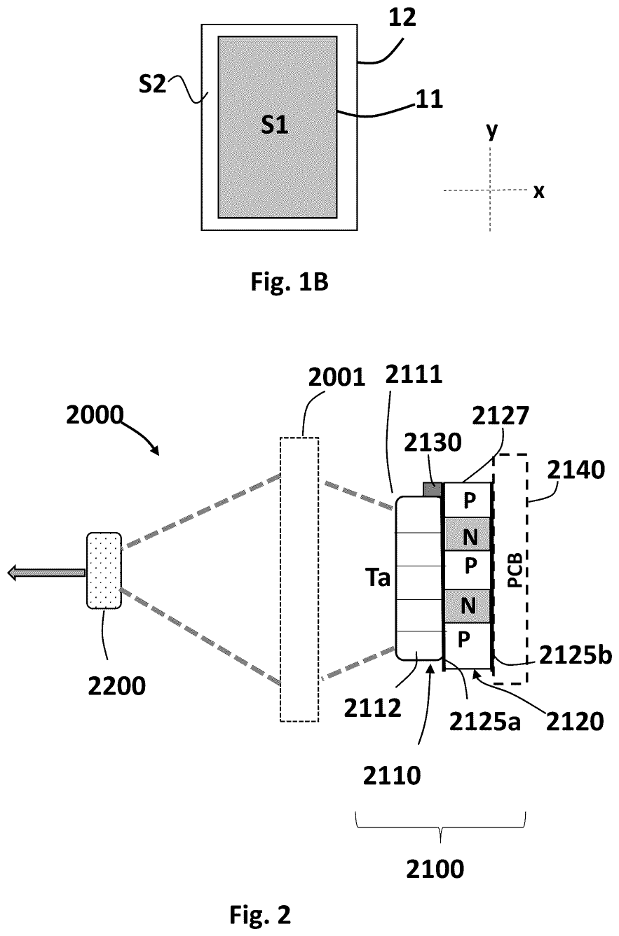

Reference is now made to Fig. 1A, schematically showing a laser diode subsystem (LDS) 1000, according to some embodiments.

The LDS 1000 may include:
a laser diode assembly (LDA) 1100 that may include one or more laser diode stacks, each laser diode stack having one or more laser diode bars of one or more laser diode emitters;
a thermal control subsystem 1200 that includes:
(i) a thermal unit (TU) 1210 configured for heating and cooling and/or removal of heat from the laser diode stack of the LDA 1100;
(ii) a measuring device 1220, located in a vicinity of the laser diode stack of the LDA 1100 and configured for measuring a parameter value that is associated with the ambient temperature Ta of the laser diode stack of the LDA 1100, such as a thermistor; and
(iii) a main controller 1230 communicatively associated with the thermal unit 1210, the measuring device 1220 and optionally also with LDA 1100.

According to some embodiments, the TU 1210 may include an electronically controllable TEC 1211 and optionally also a heat spreader such as a heat sink 1212.

The TEC 1211 may have a first plate (hot plate) and a second plate (cold plate) with an alternating N-type and P-type semiconductor elements medium located between the two plates.

The first and second plates of the TEC 1211 may be made of highly thermally conductive material(s) to quickly transfer heat to or from the LDA 1100.

A TU surface 12 (e.g., a surface of the first plate of the TEC 1211) may be coupled to a corresponding LDA surface 11 of the LDA 1100 such as to form a “contact area” S1 therebetween (e.g., by soldering them to one another using a thermally conductive soldering material). The contact area S1 may be equal to or slightly smaller than an area of the corresponding (counter-facing) LDA surface 11, such that the entire or most of the footprint of the LDA 1100 is in direct thermal contact with the TU surface 12 and such that the ratios between the contact surface area S1 and the TU surface area S2: S1:S2 is as close to 1:1 as possible (e.g., in this example about 1:1.5) and does not exceed an upper (maximum) ratio threshold of 1:4 or 1:2, for example.

Minimizing the difference between the TU surface area S2 and the LDA surface 11 area which forms the contact area S1, enables a much faster temperature-control. Since the size (TU surface area S2 and optionally also mass/volume etc.) of the TU surface 12 of the first plate of the TEC 1211 is close to the size of the LDA surface 11, heat cannot spread much away from the contact area S1. Therefore, heat produced by the TEC 1211 can be transferred directly and quickly from the TEC 1211 to the LDB(s) of the LDA 1100 when the LDA 1100 is to be heated in a much more efficient manner directing most of the energy to the LDA 1100 avoiding or reducing heat from being channelled to any other component or part. Heat exhausted from the LDA 1100 can be quickly removed or actively cooled by the TEC 1211, when used for LDA cooling, as the exhausted heat will be directly channelled from the LDA 1100 to the first plate of the TEC 1211 and from thereon to the second plate of the TEC 1211.

According to some embodiments, t connector receptacles such as connector receptacles 23 and 24 may be used to connect the LDA 1100 to the TU 1210. The connector receptacles 23 and 24 may be configured for receiving in sockets or openings 23a and 24a thereof, corresponding fastening and/or electrical connectors or connectors.

According to some embodiments, the connector receptacles 23 and 24 and/or the corresponding connectors (not shown) may be made of low thermal conductivity materials and may be used for mechanical and/or electrical connection of the LDA 1100 to other components, devices, power supply, etc.

According to some embodiments, the size, mass, geometry, and/or configuration of the LDA 1100 may be designed in a customized manner to further improve temperature-control efficiency. E.g., by using a more compact/smaller configuration stacking all emitters in a much more tight and compact manner, using smaller spacers or not using any spacers, reducing LDA 1100 mass by selecting lighter TU materials of similar thermal properties, removing most of standard used laser diode stacks' holding plates, reducing electrical connector's overall number and/or size etc.

According to some embodiments, the laser diode subsystem 1000 may be arranged such that the emitters of its LDA 1100 emit light in a direction (such as shown by arrow E in FIG. 1A) that is angular (e.g., perpendicular) to a plane of the contact surface area S1.

According to some embodiments the LDA 1100 may be of a low mass such as below one gram.

FIG. 2 shows a schematic illustration of a diode pumped solid state laser (DPSSL) system 2000, according to some embodiments. The DPSSL system 2000 includes at least:
a laser diode subsystem 2100 that includes at least: (i) a LDA 2110 having a laser diode stack including a single laser diode bar 2111 of multiple laser diode emitters 2112; (ii) one or more temperature measuring devices 2130 such as a thermistor; (iii) a temperature control subsystem that includes a TEC 2120; and (iv) a main controller 2140 implementable using a PCB;
a gain medium 2200, which may be an clement such as a Nd:YAG rod having one or more main optimal absorption wavelengths WL1=795 nm and WL2=808 nm, and may be configured to output an optical beam of a wavelength or a narrow wavelength band that is different than the emission wavelength of the emitters 2112; and optionally also:
an optical setup 2001 including one or more optical elements and/or optical devices, configured to direct and optionally concentrate light emanating from the laser diode emitters 2112 to the gain medium 2200 for optimal illumination of the gain medium 2200. E.g., by creating a light spot (herein also “spot”) absorbable by the gain medium 2200, where the spot may be configured by the optical setup 2001: (a) to be of a desired size, (b) to imping the gain medium 2200 at a desired designated gain medium area/surface/spot, and/or (c) to imping the gain medium 2200 at a desired beam propagation direction angle.

The main controller 2140 may be configured for real-time, ongoing or periodic receiving of temperature related data/signals from the measuring device 2130, which may be located in a vicinity of the laser diode bar 2111; process the received data/signals to determine the real time updated ambient temperature Ta of the laser diode bar 2111; determine (e.g., calculate) the temperature difference DT between the updated ambient temperature Ta and a desired operation temperature Td, and control the TEC 2120 for heating or heat removal/cooling of the laser diode bar 2111.

According to some embodiments, as shown in FIG. 2, the TEC 2120 may include: a first (hot) plate 2125a and a second (cold) plate 2125b, made of a thermally conductive material; and an N-P semiconductor layer 2127, located between the first and second plates 2125a and 2125b.

One side (which may be flat) of the first (hot) plate 2125a, that does not face the N-P semiconductor layer 2127, is in direct contact with a counter-facing side of the laser diode bar 2111 and has a similar surface area size to the surface area size of the laser diode bar 2111, such that at least most of the surface area of the entire laser diode bar 2111 side that is in direct contact with the first (hot) plate 2125a, is covered/engulfed by the surface area of the first (hot) plate 2125a side.

The combination of: the direct contact between the TEC 2120 first (hot) plate 2125a, the similar sizes of their surface areas (e.g., a ratio of about 1:1.5 between the first plate 2125a surface area: and the laser diode bar 2111 surface area), and the design in which the first (hot) plate 2125a surface area engulfs (completely covers) at least most of the corresponding surface area of the laser diode bar 2111, for improved power consumption and temperature-control speed. Increasing temperature adjustment/control-speed enables a dramatically improved energy consumption management, inter alia, in cases in which the updated ambient temperature Ta significantly deviates from the desired operation temperature Td, sometimes by a temperature difference of up to 70 degree Celsius. For example, to reduce power consumption, the emitters 2112 and optionally the entire DPSSL system 2000, may be set to be kept deactivated, when the emission of laser beam outputted by the DPSSL system 2000 is not required, and only activated/operated shortly (e.g., within several seconds) before optimal DPSSL laser beam emission is required, which can cause such large temperature differences DTs to be overcome within minimum time such as within a second or two. As the updated ambient temperature Ta in these cases may be the external/environmental natural temperature, where the (closest) desired operation temperature Td may be known and unchangeable, in opposed to a temperature stabilization maintenance operation mode, in which the DPSSL system 2000 is to output laser beam over a more extended periods of operations, where once the desired operation temperature Td is achieved the temperature control subsystem 2120 is set to adjust much smaller temperature differences.

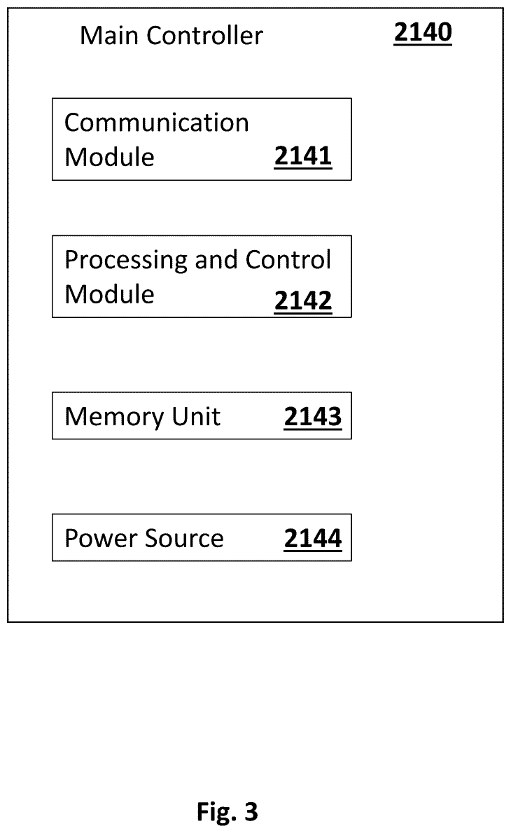

FIG. 3 is a block diagram, schematically illustrating optional modules operable by a main controller such as main controller 2140 of the laser diode subsystem 2100, according to some embodiments. The main controller 2140 may include:
a communication module 2141, configured to receive data/signals from the one or more measuring devices such as measuring device 2130 of the temperature control subsystem 2120 of the laser diode subsystem 2100, the received signals indicative of the updated ambient temperature Ta of the laser diode stack(s)/bar(s)/emitter(s) of the laser diode assembly;
a processing and control unit 2142, configured to: (a) process (in real time) received measured data/signals, (b) determine based thereon, an updated ambient temperature Ta of the laser diode emitters/bar(s), (c) determine (calculate) an updated temperature difference DT between the updated ambient temperature Ta and a (selected) desired operation temperature Td, (d) automatically operate TU of the laser diode subsystem 2100 and optionally also the laser diode emitters 2112, based on the determined temperature difference and the (selected) desired operation temperature Td, in order to achieve the determined desired operation temperature Td;
a memory unit 2143 for storing operation commands/instructions/plans, received data from measuring device(s) and/or determined values such as updated ambient temperatures and/or temperature differences; and
a power source such as one or more batteries and/or a power supply for supplying power to one or more of: the main controller 2140 itself, the measuring device 2130, the TEC of the temperature control subsystem 2120, the laser diode (LD) emitters 2112, devices of the optical setup 2001 etc.

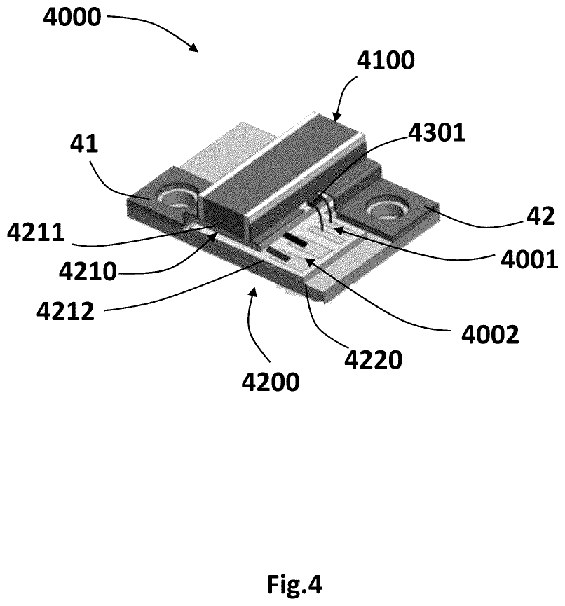

FIG. 4 shows a schematic illustration of a laser diode subsystem 4000, according to other embodiments. The laser diode subsystem 4000 may include:
a laser diode assembly (LDA) 4100 that may include one or more laser diode stacks, each laser diode stack having one or more laser diode bars of one or more laser diode emitters;
a thermal control subsystem 4200 that may include at least a TU including a TEC 4210 having two heat conducting plates: a first plate 4211 and a second plate 4112 and optionally also a heat sink 4220 thermally coupled to the second plate 4112 of the TEC 4210.

According to some embodiments, the LDA 4100 may also include one or more connections such as connections 4001 for connecting to a measuring device such one or more thermistors 4301.

Other electrical connection means may be used such as connections 4002 for electrically connecting the TEC 4210 for example to the main controller (not shown) and/or to one or more power supply means.

According to some embodiments, the first plate 4211 of the TEC 4210 may integrally connect to one or more connector receptacles or drill such as connector receptacles 41 and 42, configured and located for receiving in sockets or openings thereof, corresponding fastening and/or electrical connectors, which may be made of very low thermal conductive material(s).

The first plate 4211 of the TEC 4210 may be thermally coupled to a lower surface of the LDA 4100 e.g., by soldering the LDA 4100 to the first plate 4211 of the TEC 4210 using a thermally conductive soldering material, such that the surface area of the contacting side of the LDA 4100 and the contacting surface are of the TEC's first plate 4211 (which is equal to the contact area S1) is close to the TU contact surface area S2.

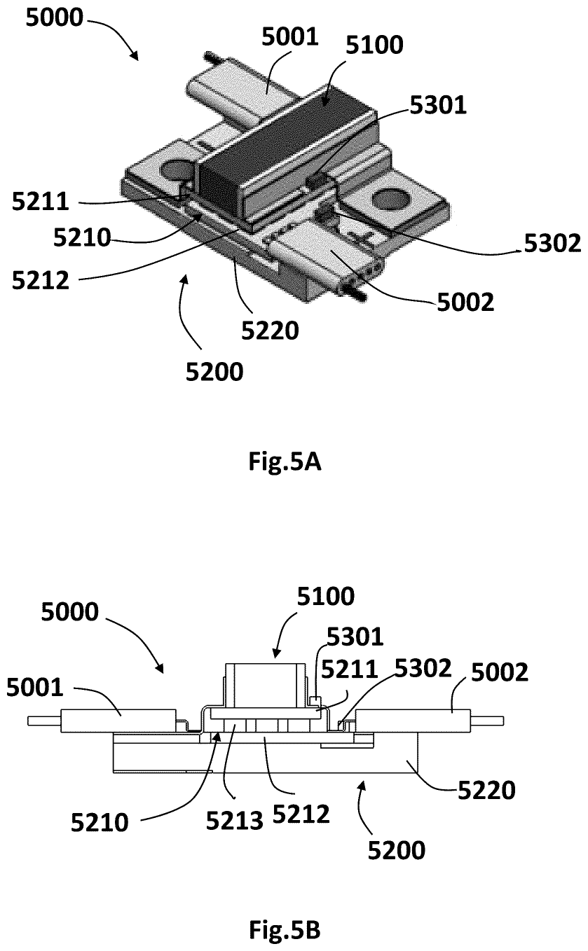

FIGS. 5A and 5B show a schematic illustration of a laser diode subsystem 5000 having two thermistors 5301 and 5302 for improving accuracy in measuring LDA 5100 temperature, according to other embodiments.

The laser diode subsystem 5000 may include:
a laser diode assembly (LDA) 5100 that may include one or more laser diode stacks, each laser diode stack having one or more laser diode bars of one or more laser diode emitters;
a thermal control subsystem 5200 that may include at least a TU including a TEC 5210 having two heat conducting plates: a first plate 5211 and a second plate 5212 having a N-P semi conductive layer 5213 therebetween, and optionally also a heat sink 5220 thermally coupled to the second plate 5212 of the TEC 5210;
thermistor 5301 located and configured to directly measure temperate Ta of the LDA 5100 and thermistor 5302 located and configured to measure temperate of the TU; and
electrical connectors 5001 and 5002 for connecting the TEC 5210 and/or the thermistor(s) 5301 and 5302, e.g., to a power supply source and/or to other electrical system components.

The first plate 5211 of the TEC 5210 may be thermally coupled to a lower surface of the LDA 5100 e.g., by soldering the LDA 5100 to the first plate 5211 of the TEC 5210 using a thermally conductive soldering material, such that the surface area of the contacting side of the LDA 5100 and the contacting surface are of the TEC's first plate 5211 (which is equal to the contact area S1) is similar in size to the TU contact surface area S2.

According to some embodiments, as shown in FIGS. 5A and 5B, one of the thermistors such as first thermistor 5301 may be located adjacent to the LDA 5100 for measuring ambient temperature Ta(LDA) of the LDA 5100 while the other (second) thermistor 5302 may be located adjacent to one of the TEC plates such as to the second plate 5212, for measuring ambient temperature Ta(TU) of the TEC 5210. This configuration may enable also measuring/calculating the ambient temperature difference DTa (DTa=Ta(LDA)−Ta(TU) or (DTa=Ta(TU)−Ta(LDA)) between the TU (e.g., the TEC 5210) and the LDA 5100, for example, for measuring/determining TU/TEC 5210 performances such as heating/cooling speeds, heat transfer maximal/minimal capacities of the TU/TEC 5210 etc.

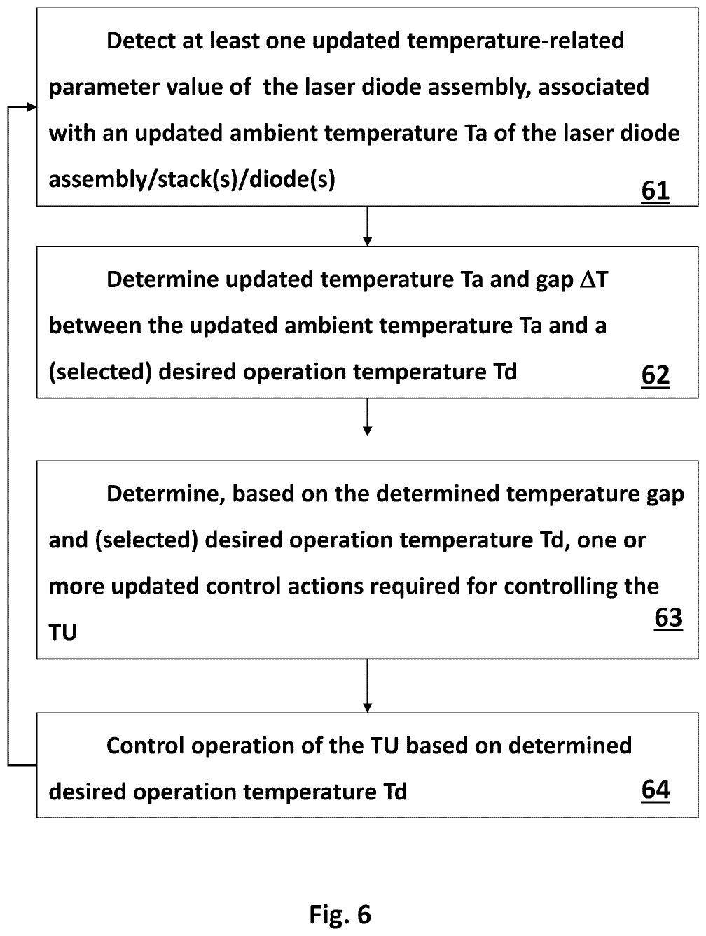

FIG. 6 is a flowchart, schematically illustrating a method for automatic controlling temperature of a laser diode assembly, based on real time and automated fast measuring of one or more parameter values associated with an updated temperature of a laser diode bar(s)/stack(s) of the laser diode subsystem, according to some embodiments.

The method may include:
detecting at least one updated temperature-related parameter value of the laser diode assembly 61, the updated temperature-related parameter being associated with an updated ambient temperature Ta of the laser diode assembly/stack(s)/diode(s);
determining updated temperature Ta, based on the detected updated temperature related parameter value and determining updated difference DT between the updated ambient temperature Ta and a (closest/selected) desired operation temperature Td 62;
determining, based on the determined updated temperature difference DT and (closest/selected) desired operation temperature Td, one or more updated control actions required for controlling the TU, required for achieving the determined desired operation temperature Td in the most optimal manner (e.g., within minimum time) 63; and
controlling operation of the TU and optionally also of the LD emitters, of the laser diode subsystem, based on determined desired operation temperature Td 64.

According to some embodiments, the entire process steps 61-64 may all be carried out automatically in an ongoing or periodic manner.

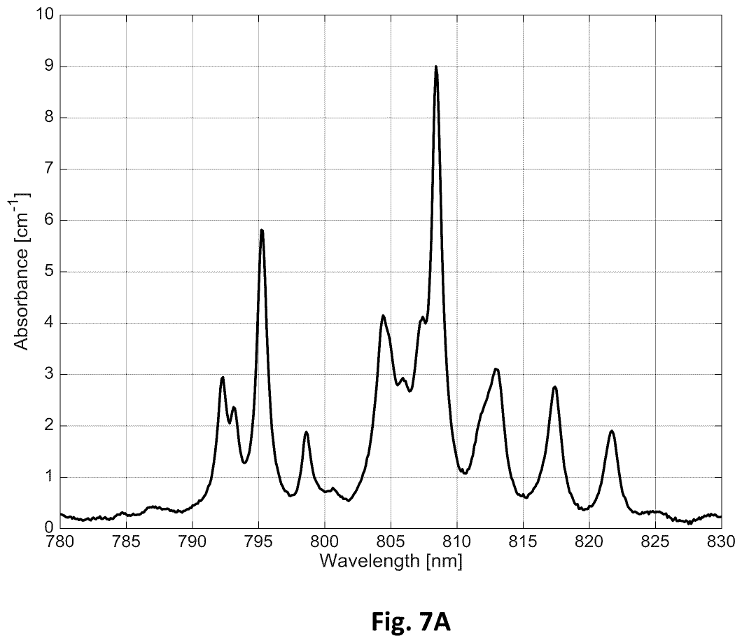

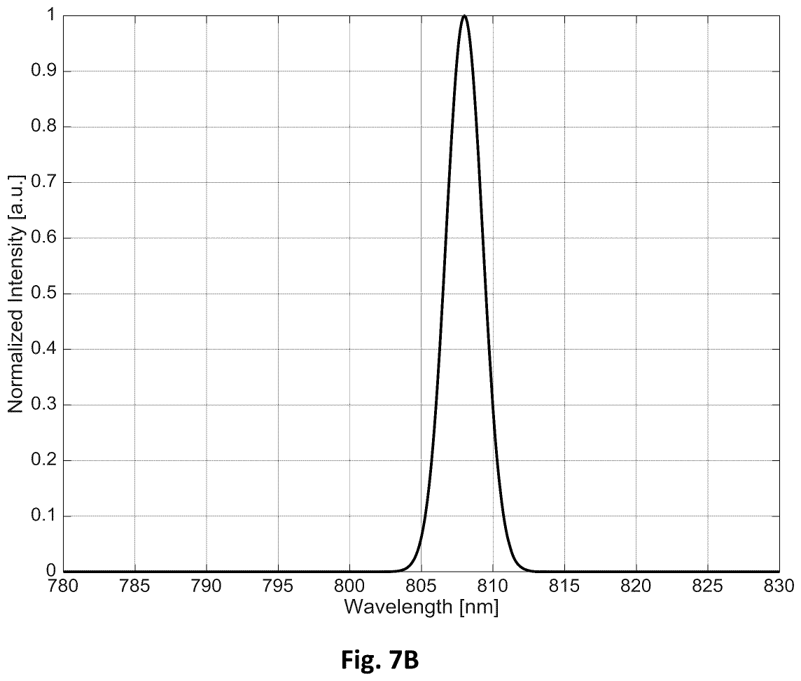

Reference is now made to FIGS. 7A, which shows the absorption lines of Nd:YAG gain medium. It is clear that the Nd:Yag gain medium has highest absorption at the wavelengths: WL1=795 nm and WL2=808 nm.

FIG. 7B shows spectral behaviour of a laser diode emitter when in a temperature of 70 degree Celsius (for example) and when using a power consumption current of 170 A (Ampere), for example, or at the laser diode designed operating current. It is shown that at this temperature Td=70° C., the emission WL peak is at 808 nm having a relatively narrow emission band of about 3 nm. Considering a 0.27 nm shift from the emission WL peak, for each 1 Degree Celsius, this LD emitter is expected to output an intensity peak at 794.5 nm at 20° C. (a difference of 50oC from Td) calculated by: 808(nm)−0.27(nm/° C.)*50° C.=794.5 nm. This emission WL of ˜795 nm of light emitted by the LD emitter will be well absorbed by the Nd:YAG gain medium and therefore, the DPSSL system will be able to produce a significant pumped gain.

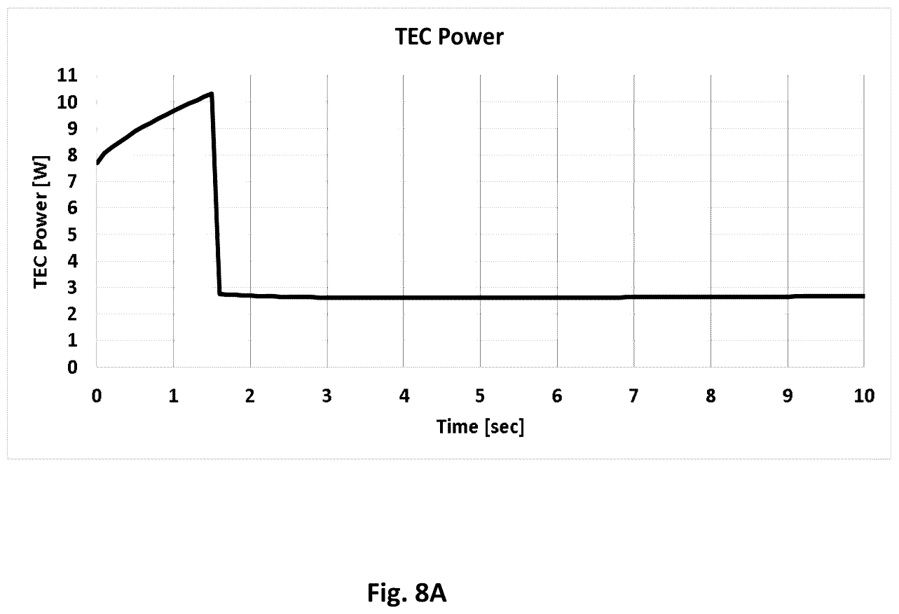

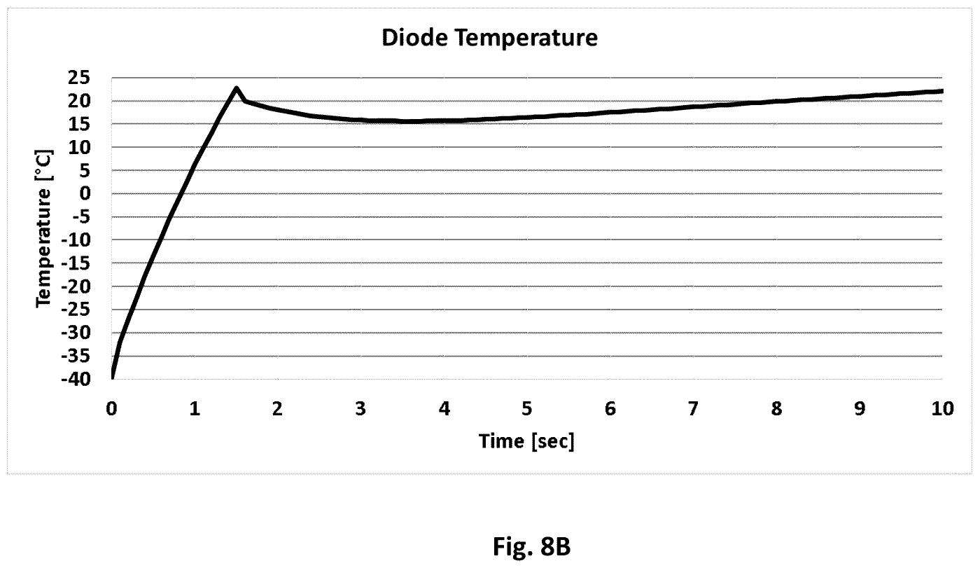

FIGS. 8A and 8B show time-dependent laser diode bar(s) estimated (simulated) performances of the temperature control subsystem when not being inspected by a control circuit/feedback-subsystem (power consumption and temperature time-related behaviour), indicative of estimated laser diode subsystem's time-related responsivity rate, using a laser diode subsystem according to some embodiments. It is shown (FIG. 8B) that the bar has been heated by about +63oC in less than 2 seconds (in about 1 second) from an ambient temperature Ta of (−40)° C. up to (+23)° C. and then stabilized to a value that is proximal to the value of the desired operation temperature Td (of (+20)° C.) within a little more than 1 second. Correspondingly, the main power consumption of about 10 W (Watt), for heating the LD bar was done within the first second, where the power consumption then reduced dramatically to about 2 W for stabilizing the temperature Td, and/or when the LD bar is deactivated (using power only for maintaining the desired operation temperature Td), once already achieved or exceeded.

Since this simulation was done without using a continuous feedback and control means, its performances are lower than would be expected if a control feedback loop/circuit was used, which continuously measures temperature differences DT between the LDA ambient temperature Ta and the desired operation temperature Td and continuously or near-continuously adjusts the temperature to achieve the desired operation temperature Td. Therefore, in this case, the system was able to reach the exact value of the desired operation temperature Td of (+20)° C. within about 2 seconds.

A power-consumption behaviour that is correlative to the temperature-changing behaviour of FIG. 8B, may be seen in FIG. 8A, showing how the heating required a power consumption of about 10 W only for about 1.5 seconds (less than 2 seconds) for the initial heating of the emitter(s) from an ambient temperature Ta to a little over the desired operation temperature Td in a case of a significant temperature difference of about 60oC. After the initial heating the stabilization of the desired operation temperature Td requires much less energy/power consumption and the power consumption is substantially stable at about 2 W. Again, this is achievable due to the very low mass of the diode bars.

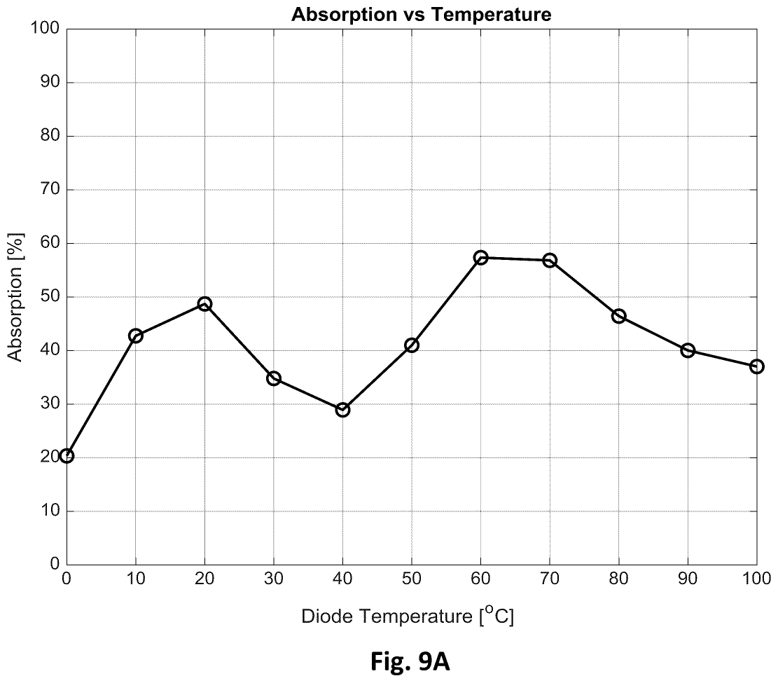

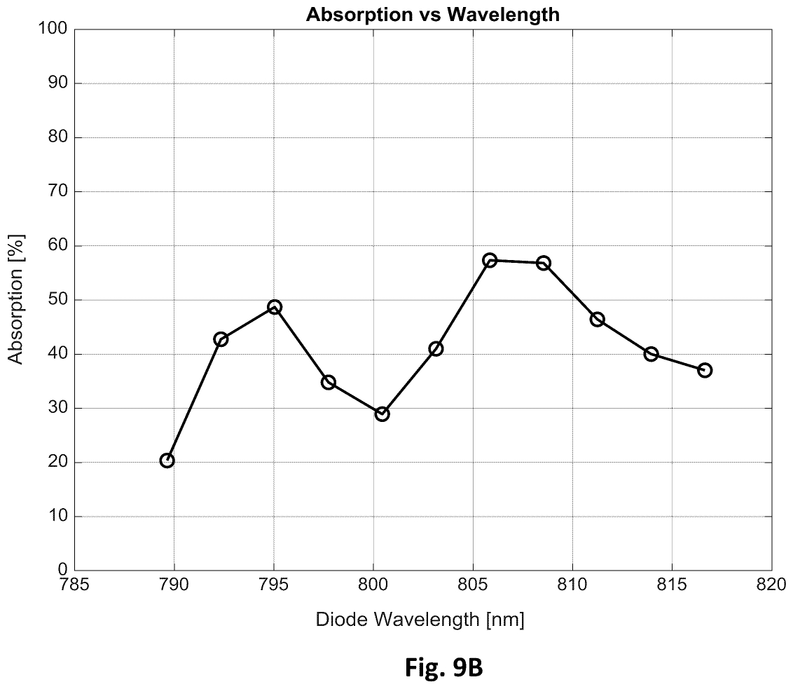

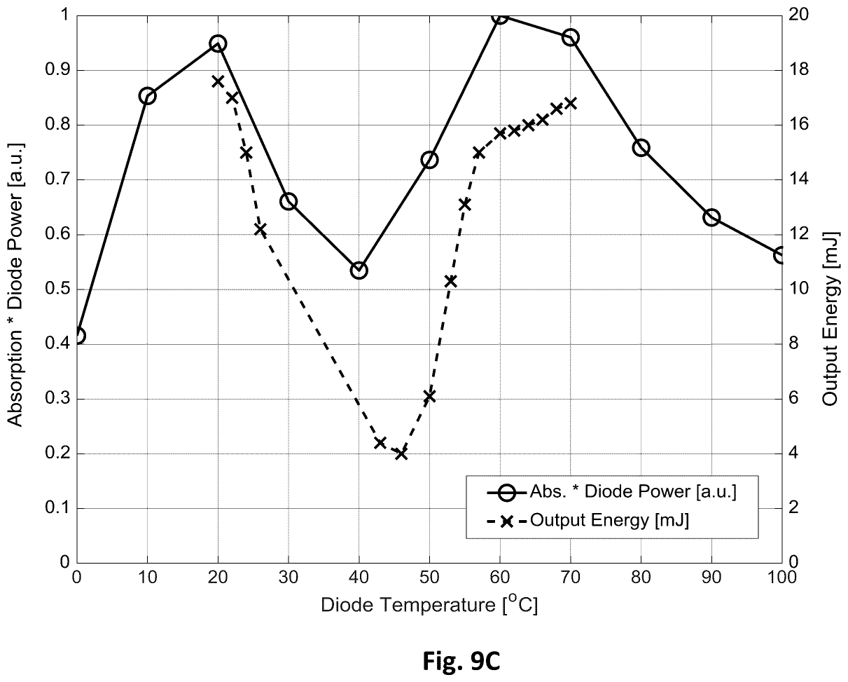

FIGS. 9A-9C show calculated correlations in gain medium absorption based
on bar's/emitter's temperature and emitter's emission wavelength(s), according to some embodiments:
FIG. 9A shows gain medium absorption performances in relation to bar's/emitter's temperature;
FIG. 9B shows gain medium absorption performances in relation to bar's/emitter's emission wavelength; and
FIG. 9C shows calculated product of gain medium absorption efficiency with emitter's/bar's temperature-related output power performances' dependency (straight line). FIG. 9C also shows a measured output energy from an oscillator as a function of the pump diode temperature (dashed line). As can be seen the measured output energy closely follows and correlates to the theoretical calculations, thus proving the feasibility of the suggested concept.

The simulations for producing the estimated absorption performances shown in FIGS. 9A-9B were made for LD emitters targeted at emission of desired emission WLs of 795 nm and 808 nm at corresponding desired operation temperatures of Td1=20° C. and Td2=68° C., for corresponding with optimal absorption WLs of a cylindrical shaped ND:YAG gain medium, having a 0.7% Nd doping and a 4 mm cylinder diameter. The simulation also used a beam tracing program/method known as Trace-pro, for calculating dependency of the gain medium's absorption efficiency in LD emitter's temperature at an overall temperature-range of 100° C. (between (−30° C. to +70° C.). FIGS. 9A and 9B show the strong dependency of the absorption efficiency's dependency in the emitter's temperature and LD emitter's emission WL as well as the correlation therebetween and the strong abs option of the gain medium at the optimal/desired WLs 808 nm and 795 nm achievable when reaching their corresponding emitter's desired operation temperatures: Td1=20° C. and Td2=68° C., respectively.

### EXAMPLES

Example 1 is a laser diode subsystem comprising at least:
(i) a laser diode assembly comprising at least one laser diode (LD) stack that comprises at least one LD bar each LD bar (LDB?) comprising at least one LD emitter, wherein the at least one LD emitter of each LDB has at least one emission wavelength (WL) when operated at a corresponding desired operation temperature Td; and
(ii) a temperature control subsystem comprising at least:
a thermal unit (TU) configured to control temperature of the at least one LD emitter;
at least one measuring device configured to detect at least one updated temperature-related parameter value of the at least one LD emitter of the laser diode assembly, the updated temperature-related parameter value being associated with an updated ambient temperature Ta in an area of the at least one LD emitter; and
a main controller operatively associated with the TU and with the at least one measuring device, for controlling operation of the TU, based on the detected updated temperature related parameter value and the at least one desired operation temperature Td of the at least one LD emitter,
wherein at least one side of the TU is in direct contact with a corresponding side of each LD stack of the laser diode assembly for direct thermal contact between the TU and each LD stack, and wherein the size of the TU corresponds to the size of the laser diode assembly, for minimizing the mass to be heated or cooled, for increasing temperature-control speed, by reducing time of adjusting of the temperature of the at least one LD emitter from an updated ambient temperature Ta to a desired operation temperature Td, for achieving an emission WL of the at least one LD emitter, that corresponds to the desired operation temperature Td.

In example 2, the subject matter of example 1 may include, wherein a ratio between the overall size, and/or dimensions of the TU corresponds to an overall size, and/or dimensions of the diode assembly or of a footprint of the diode assembly.

In example 3, the subject matter of example 2 may include, wherein a ratio R between a contact surface area S1 between the TU and the at least one diode stack of the diode assembly and an overall TU contact surface area S2 of the at least one side of the TU that is in direct contact with the at least one laser diode stack of the diode assembly, is equal to or higher than 1:4: S1/S2=R≥0.25.

In example 4, the subject matter of example 3 may include, wherein the ratio R between the contact surface area S1 and the overall TU contact surface area S2 is equal to or higher than 1:2: R≥0.5.

In example 5, the subject matter of any one or more of examples 1 to 4 may include, wherein the direct contact between the TU and the at least one laser diode stack is done by soldering of one side of each laser diode stack to one side of the TU, by using a soldering material.

In example 6, the subject matter of example 5 may include, wherein the soldering material has similar or same thermal expansion coefficient (CTE) as that of the at least one side of the TU connecting to the at least one diode stack of the diode assembly and/or as that of the at least one side of each laser diode stack connecting to the TU.

In example 7, the subject matter of any one or more of examples 1 to 6 may include, wherein each laser diode stack of the diode assembly comprises multiple diode bars, each laser diode bar comprising multiple emitters, and wherein each laser diode stack further comprises spacers, separating the diode bars in each laser diode stack from one another, wherein the at least one side of the TU is in direct contact with the spacers of the diode stack.

In example 8, the subject matter of any one or more of examples 1 to 7 may include, wherein the TU directly connects to each laser diode stack such that light emitted from each of the diodes of each of the diode stacks is directed to a direction that is angular to the at least one TU connecting side, forming a non-zero angle between a surface or a plane of each TU connecting side and the direction of emitted light from each laser diode.

In example 9, the subject matter of example 8 may include, wherein the nonzero angle formed between the plane or the surface of the TU side that connects to the at last one diode stack, and the direction of light emitted from each laser diode is between 30-150 degrees.

In example 10, the subject matter of any one or more of examples 1 to 9 may include, wherein the laser diode subsystem further comprises one or more connectors for fixating the TU to the diode assembly, wherein at least one of the one or more connectors is made of a non-conductive thermally and/or electrically material.

In example 11, the subject matter of any one or more of examples 1 to 10 may include, wherein the TU comprises a thermoelectric cooler (TEC).

In example 12, the subject matter of any one or more of examples 1 to 11 may include, wherein the TU comprises a TEC and a thermal spreader comprising one or more thermal conductive elements.

In example 13, the subject matter of any one or more of examples 1 to 12 may include, wherein the at least one measuring device of the temperature control subsystem comprises one or more temperature sensors at least one therefor being located near the diode assembly.

In example 14, the subject matter of example 13 may include, wherein at least one of the one or more temperature sensors has a response time that is lower than 2 second.

In example 15, the subject matter of any one or more of examples 1 to 14 may include, wherein the laser diode subsystem further comprises at least one printed circuit board (PCB), wherein the TU is carried by or attached directly to the PCB.

In example 16, the subject matter of any one or more of examples 1 to 15 may include, wherein the at least one measuring device, the TU and the laser diode assembly are all located within a diode pumped solid state laser (DPSSL) system that also comprises the laser diode assembly and a solid-state gain medium, wherein the at least one desired operation temperature Td of the at least one LD emitter of each LD bar, corresponds to absorption properties of the gain medium.

In example 17, the subject matter of any one or more of examples 1 to 16 may include, wherein the main controller is configured at least to:
receive in real time or near real time updated temperature data from the at least one measuring device, the updated temperature data being indicative at least of updated ambient temperature parameter value Ta of the diode assembly;
determine updated ambient temperature Ta, based on received updated temperature data;
determine an updated temperature difference DT between the desired operation
temperature value Td and determined updated ambient temperature value, in real time or near real time, in relation to the time of receiving of the updated temperature data;
determine, in real time or near real time, in relation to the time of determination of the corresponding updated temperature difference DT, one or more updated control actions required for controlling the TU for fastest achievement of the desired operation temperature Td or for achieving a temperature that deviates from the desired operation temperature Td below a predetermined temperature deviation threshold TDth; and
control the TU based on determined one or more control actions, in real time or near real time, in relation to the time of determining of the corresponding one or more control actions.

In example 18, the subject matter of any one or more of examples 1 to 17 may include, wherein the main controller comprises at least:
a communication module for receiving and transmitting data at least from and to the TU and at least for receiving data from the at least one measuring device, via one or more communication links;
a processing and control module for processing data received from the at least one measuring device, determine, based on processing results, one or more updated temperature control actions, and controlling temperature of the laser diode assembly based on determined one or more updated control actions;
a memory unit.

In example 19, the subject matter of any one or more of examples 1 to 18 may include, wherein each desired operation temperature Td of each LD bar is associated with a corresponding desired emission wavelength (WL) of the corresponding at least one LD emitter of the corresponding LD bar.

In example 20, the subject matter of any one or more of examples 1 to 19 may include, wherein all LD emitters of each LDB have the same at least one desired operation temperature Td.

In example 21, the subject matter of example 20 may include, wherein all LD emitters of each LDB are light emitting diodes (LEDs).

In example 22, the subject matter of any one or more of examples 1 to 21 may include, wherein the laser diode subsystem is configured to adjust temperature of the at least one LD emitter from its updated ambient temperature Ta to the desired operation temperature Td for an absolute value of a temperature difference DT between the updated ambient temperature Ta and the at least one desired operation temperature Td of up to 60 degree Celsius within a maximum adjustment time of 2 seconds.

In example 23, the subject matter of any one or more of examples 1 to 22 may include, wherein the main controller is located externally to and/or remotely from the laser diode assembly.

In example 24, the subject matter of any one or more of examples 1 to 23 may include, wherein the main controller comprises a printed circuit board (PCB) connected to the TU and to the at least one measuring device, the PCB being located in close proximity to the laser diode assembly.

In example 25, the subject matter of any one or more of examples 1 to 23 may include, wherein the mass of the laser diode assembly is equal to or lower than one gram.

Example 26 is a diode-pumped solid state laser (DPSSL) system comprising at least:
a DPSSL device comprising at least:
(i) a laser diode assembly comprising at least one laser diode (LD) stack that comprises at least one LD bar, each LD bar comprising at least one LD emitter, each LD emitter being configured to emit light of at least one emission wavelength (WL) when under a corresponding at least one emission desired operation temperature Td;
(ii) a solid-state (SS) gain medium; and
(iii) a thermal unit (TU) configured to control temperature of the LD stack; and
(iv) at least one measuring device configured to detect at least one updated temperature-related parameter value of the at least one LD emitter, the updated temperature related parameter value being associated with an updated ambient temperature Ta in an area of the at least one LDB, wherein the SS gain medium, the at least one measuring device and the TU and the laser diode assembly are all located within the DPSSL device, and wherein the at least one desired operation temperature Td of the at least one LD emitter of each LD bar, corresponds to absorption properties of the gain medium, and
a main controller operatively associated with the TU and with the at least one measuring device, for controlling operation of the TU, based on the detected updated temperature related parameter value and the at least one desired operation temperature Td of the at least one LD emitter, wherein at least one side of the TU is in direct contact with a corresponding side of each LD stack of the laser diode assembly for direct thermal contact between the TU and each laser diode stack, and wherein the size of the TU corresponds to the size of the laser diode assembly, for increasing temperature-control speed, by reducing time of adjusting of the temperature of the at least one LD emitter from an updated ambient temperature Ta to a desired operation temperature Td, for achieving an emission WL of the at least one LD emitter, that corresponds to the desired operation temperature Td, which corresponds with at least one absorption property of the SS gain medium.

In example 27, the subject matter of example 26 may include, wherein the gain medium comprises one of: yttrium aluminium garnet (YAG) based material; a doped YAG material doped with one of: neodymium (Nd); ytterbium (Yb), thulium (Tm), holmium (Ho), erbium (Er).

Example 28 is a method for temperature control, the method comprising at least:
providing a laser diode assembly comprising at least one laser diode (LD) stack that comprises at least one LD bar, each LD bar comprising at least one LD emitter, each LD emitter being configured to emit light of at least one emission wavelength (WL) when under a corresponding at least one emission desired operation temperature Td;
providing a thermal unit (TU) configured to control temperature of the at least one LD emitter;
providing at least one measuring device;
detecting at least one updated temperature-related parameter value of the at least one LD emitter, the updated temperature-related parameter value being associated with an updated ambient temperature Ta in an area of the at least one LD emitter, using the at least one measuring device;
controlling operation of the TU, based on the detected updated temperature related parameter value and the at least one desired operation temperature Td of the at least one LD emitter, wherein at least one side of the TU is in direct contact with a corresponding side of each laser diode stack of the laser diode assembly for direct thermal contact between the TU and each laser diode stack, and wherein the size of the TU corresponds to the size of the laser diode assembly, for minimizing laser diode mass, for increasing temperature-control speed, by reducing time of adjusting of the temperature of the at least one LD emitter from an updated ambient temperature Ta to a desired operation temperature Td, for achieving an emission WL of the at least one LD emitter, that corresponds to the desired operation temperature Td.

In example 29, the subject matter of example 28 may include, wherein the method further comprises:
(a) receiving in real time or near real time updated temperature data from the at least one measuring device, the updated temperature data being indicative at least of updated ambient temperature parameter value Ta of the diode assembly;
(b) determining an updated temperature difference DT between the desired operation temperature value Td and updated ambient temperature value Ta: DT=Td−Ta or DT=Ta−Td, in real time or near real time, in relation to the time of receiving of the updated temperature data;
(c) determining, in real time or near real time, in relation to the time of determination of the corresponding updated temperature difference DT, one or more updated control actions required for controlling the TU for fastest achievement of the desired operation temperature Td or for achieving a temperature that deviates from the desired operation temperature Td below a predetermined temperature deviation threshold TDth; and
(d) controlling the TU based on determined one or more control actions, in real time or near real time, in relation to the time of determining of the corresponding one or more control actions.

In example 30, the subject matter of any one or more of examples 28 to 29 may include, wherein steps (a) to (d) are automatically performed by using a main controller.

In example 31, the subject matter of any one or more of examples 28 to 30 may include, wherein steps (a) to (d) are performable in real time or rear real time.

In example 32, the subject matter of any one or more of examples 28 to 31 may include, wherein a ratio between the overall size, and/or dimensions of the TU corresponds to an overall size, and/or dimensions of the diode assembly or of a footprint of the diode assembly.

In example 33, the subject matter of example 32 may include, wherein a ratio R between a contact surface area S1 between the TU and the at least one diode stack of the diode assembly and an overall TU contact surface area S2 of the at least one side of the TU that is in direct contact with the at least one laser diode stack of the diode assembly, is equal to or higher than 1:4: S1/S2=R≥0.25.

In example 34, the subject matter of example 33 may include, wherein the ratio R between the contact surface area S1 and the overall TU contact surface area S2 is equal to or higher than 1:2: R≥0.5.

In example 35, the subject matter of any one or more of examples 28 to 34 may include, wherein the direct contact between the TU and the at least one laser diode assembly is done by soldering of one side of each laser diode stack to one side of the TU, by using a soldering material.

In example 36, the subject matter of example 35 may include, wherein the soldering material has similar or same thermal expansion coefficient (CTE) as that of the at least one side of the TU connecting to the at least one diode stack of the diode assembly and/or as that of the at least one side of each laser diode stack connecting to the TU.

In example 37, the subject matter of any one or more of examples 28 to 36 may include, wherein the TU directly connects to each laser diode stack such that light emitted from each of the LD emitters of each LD bar is directed to a direction that is angular to the at least one TU connecting side, forming a non-zero angle between a surface or a plane of each TU connecting side and the direction of emitted light from each laser diode.

In example 38, the subject matter of example 37 may include, wherein the non zero angle formed between the plane or the surface of the TU side that connects to the at last one diode stack, and the direction of light emitted from each laser diode is between 30-150 degrees.

In example 39, the subject matter of any one or more of examples 28 to 38 may include, wherein the TU comprises a thermoelectric cooler (TEC).

In example 40, the subject matter of any one or more of examples 28 to 39 may include, wherein the TU comprises a TEC and a thermal spreader comprising one or more thermal conductive elements.

In example 41, the subject matter of any one or more of examples 28 to 40 may include, wherein the at least one measuring device of the temperature control subsystem comprises one or more temperature sensors at least one therefor being located near the laser diode assembly.

In example 42, the subject matter of any one or more of examples 28 to 41 may include, wherein the at least one measuring device, the TU and the laser diode assembly are all located within a diode pumped solid state laser (DPSSL) system that also comprises a solid-state gain medium, wherein the at least one desired operation temperature Td of the at least one LD emitter of each LDB, corresponds to absorption properties of the gain medium.

In example 43, the subject matter of any one or more of examples 28 to 42 may include, wherein all LD emitters of each LD bar are configured to emit light of the same wavelength or wavelength band when under the same each of the at least one desired operation temperature Td.

In example 44, the subject matter of any one or more of examples 28 to 43 may include, wherein the temperature controlling is done by adjusting the temperature of the at least one LD emitter from its updated ambient temperature Ta to the desired operation temperature Td for an absolute value of a temperature difference DT between the updated ambient temperature Ta and the at least one desired operation temperature Td, which is lower than a 70 degree Celsius within a maximum adjustment time of 2 seconds.

Although the above description discloses a limited number of exemplary embodiments of the invention, these embodiments should not apply any limitation to the scope of the invention, but rather be considered as exemplifications of some of the manners in which the invention can be implemented.

The method and/or processes described herein may be implemented by any one or more software, and/or hardware, element apparatus, device, mechanism, electronic and/or digital computerized system, unit, processing module, device, machine, engine, etc.

The system, module, unit, device etc. or parts thereof, may be programmed to perform particular functions pursuant to computer readable and executable instructions, rules, conditions etc. from programmable hardware and/or software based execution modules that may implement one or more methods or processes disclosed herein, and therefore can, in effect, be considered as disclosing a “special purpose computer” particular to embodiments of each disclosed method/process.

Additionally or alternatively, the methods and/or processes disclosed herein may be implemented as a computer program that may be tangibly or intangibly embodied by a special purpose computer readable signal medium. A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a non-transitory computer or machine-readable storage device and that can communicate, propagate, or transport a program for use by or in connection with apparatuses, systems, platforms, methods, operations and/or processes discussed herein.

The terms “non-transitory computer-readable storage device” and “nontransitory machine-readable storage device” may also include distribution media, intermediate storage media, execution memory of a computer, and any other medium or device capable of storing for later reading by a computer program implementing embodiments of a method disclosed herein. A computer program product can be deployed to be executed on one computer or on multiple computers at one site or distributed across multiple sites and interconnected by one or more communication networks.

The computer readable and executable instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

A module, a device, a mechanism, a unit and or a subsystem may each comprise a machine or machines executable instructions (e.g., commands). A module may be embodied by a circuit or a controller programmed to cause the system to implement the method, process and/or operation as disclosed herein. For example, a module may be implemented as a hardware circuit comprising, e.g., custom very large-scale integration (VLSI) circuits or gate arrays, an Application-specific integrated circuit (ASIC), off-the-shelf semiconductors such as logic chips, transistors, and/or other discrete components. A module may also be implemented in programmable hardware devices such as field programmable gate arrays, programmable array logic, programmable logic devices and/or the like.

In the above disclosure, unless otherwise stated, terms such as “substantially”, “about”, approximately, etc., that specify a condition or relationship characterizing a feature or features of an embodiment of the invention, are to be understood to mean that the condition or characteristic is defined to within tolerances that are acceptable for operation of the embodiment for an application for which it is intended.

It is important to note that the methods/processes and/or systems/devices/subsystems/apparatuses etc., disclosed in the above Specification, are not to be limited strictly to flowcharts and/or diagrams provided in the Drawings. For example, a method may include additional or fewer processes or steps in comparison to what is described in the figures. In addition, embodiments of the method are not necessarily limited to the chronological order as illustrated and described herein.

It is noted that terms such as “processing”, “computing”, “calculating”, “determining”, “establishing”, “analyzing”, “checking”, “estimating”, “deriving”, “selecting”, “inferring”, “identifying”, “detecting” and/or the like, may refer to operation(s) and/or process(es) of a computer, a computing platform, a computing system, or other electronic computing device(s), that manipulate and/or transform data represented as physical (e.g., electronic or optical signal) quantities within the computer's registers and/or memories into other data similarly represented as physical quantities within the computer's registers and/or memories or other information storage medium that may store instructions to perform operations and/or processes.

Terms used in the singular shall also include a plural scope, except where expressly otherwise stated or where the context otherwise requires.

In the description and claims of the present application, each of the verbs, “comprise” “include” and “have”, and conjugates thereof, are used to indicate that the object or objects of the verb are not necessarily a complete listing of components, elements or parts of the subject or subjects of the verb.

Unless otherwise stated, the use of the expression “and/or” between the last two members of a list of options for selection indicates that a selection of one or more of the listed options is appropriate and may be made i.e., enabling all possible combinations of one or more of the specified options. Further, the use of the expression “and/or” may be used interchangeably with the expressions “at least one of the following”, “any one of the following” or “one or more of the following”, followed by a listing of the various options.

It is appreciated that certain features of the invention, which are, for clarity, described in the context of separate embodiments or example, may also be provided in combination in a single embodiment. Conversely, various features of the invention, which are, for brevity, described in the context of a single embodiment, example and/or option, may also be provided separately or in any suitable sub-combination or as suitable in any other described embodiment, example or option of the invention. Certain features described in the context of various embodiments, examples and/or optional implementation are not to be considered essential features of those embodiments, unless the embodiment, example and/or optional implementation is inoperative without those elements.

It is noted that the terms “in some embodiments”, “according to some embodiments”, “according to some embodiments of the invention”, “for example”, “e.g.”, “for instance” and “optionally” may herein be used interchangeably.

The number of elements shown in the Figures should by no means be construed as limiting and is for illustrative purposes only.

It is noted that the terms “operable to” can encompass the meaning of the term “modified or configured to”. In other words, a machine “operable to” perform a task can in some embodiments, embrace a mere capability (e.g., “modified”) to perform the function and, in some other embodiments, a machine that is actually made (e.g., “configured”) to perform the function.

The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals there between.

1. A laser diode subsystem comprising at least:
(i) a laser diode (LD) assembly comprising at least one LD stack that comprises at least one LD bar each LD bar comprising at least one LD emitter, wherein the at least one LD emitter of each LD bar has at least one emission wavelength (WL) when operated at a corresponding desired operation temperature Td; and
(ii) a temperature control subsystem comprising at least:
a thermal unit (TU) configured to control temperature of the at least one LD emitter of a corresponding LD stack;
at least one measuring device configured to detect at least one updated temperature-related parameter value of the at least one LD emitter of the LD stack, the at least one updated temperature-related parameter value being associated with an updated ambient temperature Ta in an area of the at least one LD emitter; and
a main controller operatively associated with the TU and with the at least one measuring device, for controlling operation of the TU, based on the detected updated temperature related parameter value and the at least one desired operation temperature Td of the at least one LD emitter,
wherein at least one side of the TU is in direct contact with a corresponding side of each LD stack of the laser diode assembly for direct thermal contact between the TU and each LD stack, forming a contact surface area S1 between the TU and the corresponding LD stack, and
wherein a size of the contact surface area S1 is smaller than or equal to a size of an overall TU contact surface area S2 facing the LD stack such that S1≤S2, and a ratio “R” between S1:S2 is such as to reduce a mass to be heated or cooled by the TU, for increasing temperature-control speed, by reducing time of adjusting of the temperature of the at least one LD emitter from an updated ambient temperature Ta to a desired operation temperature Td, wherein the desired operation temperature Td corresponds to a desired emission wavelength (WL) of the at least one emitter.

2. The laser diode subsystem of claim 1, wherein the ratio “R” between the contact surface area S1 and the overall TU surface area S2, R=S1:S2, is higher than or equal to 1:4 such that R≥0.25 or higher than or equal to 1.2 such that R≥0.5.

3. (canceled)

4. The laser diode subsystem of any one of claim 1, wherein the direct contact between the TU and the at least one LD stack is done by soldering of one side of each laser diode stack to one side of the TU, by using a soldering material wherein the soldering material has similar or same coefficient of thermal expansion (CTE) as that of the at least one side of the TU connecting to the at least one diode stack of the diode assembly and/or as that of the at least one side of each laser diode stack connecting to the TU.

5. (canceled)

6. The diode subsystem of claim 1, wherein each LD stack of the laser diode assembly comprises multiple LD bars, each LD bar comprising multiple LD emitters, and wherein each LD stack further comprises spacers, separating the LD bars in each LD stack from one another, wherein the at least one side of the TU is in direct contact with the spacers of the respective LD stack.

7. The laser diode subsystem of claim 1, wherein the TU is thermally coupled to each LD stack such that light emitted from each LD emitter of each LD stack of the LD assembly, is directed to a direction that is angular to the at least one TU connecting side, forming a non-zero angle between a surface or a plane of each TU connecting side and propagation direction of emitted light.

8. The laser diode subsystem of claim 7, wherein the non-zero angle formed between the plane or the surface of the TU side that connects to the at last one LD stack, and the propagation direction of light emitted from each LD emitter is between 30-150 degrees.

9. The laser diode subsystem of claim 1 further comprising one or more connectors for fixating the TU to the laser diode assembly, wherein at least one of the one or more connectors is made of a thermally and/or electrically non-conductive material.

10. The laser diode subsystem of claim 1, wherein the TU comprises a thermoelectric cooler (TEC).

11. The laser diode subsystem of claim 1, wherein the TU comprises a TEC and a thermal spreader comprising one or more thermal conductive elements.

12. The laser diode subsystem of claim 1, wherein the at least one measuring device of the temperature control subsystem comprises one or more temperature sensors at least one therefore being located near the diode assembly.

13. The laser diode subsystem of claim 12, wherein at least one of the one or more temperature sensors has a response time that is lower than 2 second.

14. The laser diode subsystem of claim 1 further comprising at least one printed circuit board (PCB), wherein the TU is carried by or attached directly to the at least one PCB.

15. The laser diode subsystem of claim 1, wherein the at least one measuring device, the TU and the LD assembly are all part of a diode pumped solid state laser (DPSSL) system that also comprises a solid-state gain medium, wherein the at least one desired operation temperature Td of the at least one LD emitter of each LD bar, corresponds to absorption properties of the gain medium.

16. The laser diode subsystem of claim 1, wherein the main controller is configured at least to:
receive in real time or near real time updated temperature data from the at least one measuring device, the updated temperature data being indicative at least of updated ambient temperature parameter value Ta of the diode assembly;
determine updated ambient temperature Ta, based on received updated temperature data;
determine an updated temperature difference ΔT between a value of the desired operation temperature Td and a value of determined updated ambient temperature Ta, in real time or near real time, in relation to the time of receiving of the updated temperature data;
determine, in real time or near real time, in relation to the time of determination of the corresponding updated temperature difference ΔT, one or more updated control actions required for controlling the TU for fast achievement of the desired operation temperature Td or for achieving a temperature that deviates from the desired operation temperature Td below a predetermined temperature deviation threshold TDth; and
control the TU based on determined one or more updated control actions, in real time or near real time, in relation to time of determining of the corresponding one or more control actions.

17. The laser diode subsystem claim 1, wherein the main controller comprises at least:
a communication module for receiving and transmitting data at least from and to the TU and at least for receiving data from the at least one measuring device, via one or more communication links;
a processing and control module for processing data received from the at least one measuring device, determine, based on processing results, one or more updated temperature control actions, and controlling temperature of the laser diode assembly based on determined one or more updated control actions;
a memory unit.

18-19. (canceled)

20. The laser diode subsystem of claim 1 being configured to adjust temperature of the at least one LD emitter from its updated ambient temperature Ta to the desired operation temperature Td for an absolute value of a temperature difference ΔT between the updated ambient temperature Ta and the at least one desired operation temperature Td of up to 60 degrees Celsius within a maximum temperature adjustment time of 2 seconds.

21. The laser diode subsystem of claim 1, wherein the main controller is located externally to and/or remotely from the laser diode assembly.

22-23. (canceled)

24. A diode-pumped solid-state laser (DPSSL) system comprising at least:
(i) a laser diode (LD) assembly comprising at least one LD stack that comprises at least one LD bar, each LD bar comprising at least one LD emitter, each LD emitter being configured to emit light of at least one emission wavelength (WL) when under a corresponding at least one emission desired operation temperature Td;
(ii) a solid-state (SS) gain medium; and
(iii) a thermal unit (TU) configured to control temperature of the LD stack;
(iv) at least one measuring device configured to detect at least one updated temperature-related parameter value of the at least one LD emitter, the updated temperature-related parameter value being associated with an updated ambient temperature Ta in an area of the at least one LD bar, wherein the at least one desired operation temperature Td of the at least one LD emitter of each LD bar, corresponds to absorption properties of the gain medium,
and
(iv) a main controller operatively associated with the TU and with the at least one measuring device, for controlling operation of the TU, based on the detected updated temperature related parameter value and the at least one desired operation temperature Td of the at least one LD emitter,
wherein at least one side of the TU is in direct contact with a corresponding side of each LD stack of the laser diode assembly for direct thermal contact between the TU and each laser diode stack, forming a contact surface area S1 between the TU and the corresponding LD stack, and
wherein a size of the contact surface area S1 is smaller than or equal to a size of an overall TU contact surface area S2 facing the LD stack such that S1≤S2, and a ratio “R” between S1:S2 is such as to reduce a mass to be heated or cooled by the TU, for increasing temperature-control speed, by reducing time of adjusting of the temperature of the at least one LD emitter from an updated ambient temperature Ta to a desired operation temperature Td, wherein the desired operation temperature Td corresponds to a desired emission wavelength (WL) of the at least one emitter.

25. (canceled)

26. A method for temperature control, the method comprising at least:
providing a laser diode assembly comprising at least one laser diode (LD) stack that comprises at least one LD bar, each LD bar comprising at least one LD emitter, each LD emitter being configured to emit light of at least one emission wavelength (WL) when under a corresponding at least one emission desired operation temperature Td;
providing a thermal unit (TU) configured to control temperature of the at least one LD emitter;
providing at least one measuring device;
detecting at least one updated temperature-related parameter value of the at least one LD emitter, the updated temperature-related parameter value being associated with an updated ambient temperature Ta in an area of the at least one LD emitter, using the at least one measuring device;
controlling operation of the TU, based on the detected updated temperature related parameter value and the at least one desired operation temperature Td of the at least one LD emitter,
wherein at least one side of the TU is in direct contact with a corresponding side of each laser diode stack of the laser diode assembly for direct thermal contact between the TU and each laser diode stack, forming a contact surface area S1 between the TU and the corresponding LD stack,
and
wherein a size of the contact surface area S1 is smaller than or equal to a size of an overall TU contact surface area S2 facing the LD stack such that S1≤S2, and a ratio “R” between S1:S2 is such as to reduce a mass to be heated or cooled by the TU, for increasing temperature-control speed, by reducing time of adjusting of the temperature of the at least one LD emitter from an updated ambient temperature Ta to a desired operation temperature Td, wherein the desired operation temperature Td corresponds to a desired emission wavelength (WL) of the at least one emitter.

27. The method of claim 26 further comprising:
(a) receiving in real time or near real time updated temperature data from the at least one measuring device, the updated temperature data being indicative at least of updated ambient temperature parameter value Ta of the diode assembly;
(b) determining an updated temperature difference ΔT between the desired operation temperature value Td and updated ambient temperature value Ta: ΔT=Td−Ta or ΔT=Ta−Td, in real time or near real time, in relation to the time of receiving of the updated temperature data;
(c) determining, in real time or near real time, in relation to the time of determination of the corresponding updated temperature difference ΔT, one or more updated control actions required for controlling the TU for fast achievement of the desired operation temperature Td or for achieving a temperature that deviates from the desired operation temperature Td below a predetermined temperature deviation threshold TDth; and
(d) controlling the TU based on determined one or more control actions, in real time or near real time, in relation to the time of determining of the corresponding one or more control actions.

28-38. (canceled)

39. The method of claim 26, wherein the at least one measuring device, the TU and the laser diode assembly are all located within a diode pumped solid state laser (DPSSL) system that also comprises a solid-state gain medium, wherein the at least one desired operation temperature Td of the at least one LD emitter of each LDB, corresponds to absorption properties of the gain medium.
